(19) United States
(12) Patent Application Publication
(10) Pub. No.: US 2021/0183839 A1
(43) Pub. Date: Jun. 17, 2021

(54) SEMICONDUCTOR PACKAGE DEVICE AND METHOD OF MANUFACTURING THE SAME

(71) Applicant: Advanced Semiconductor Engineering, Inc., Kaohsiung (TW)

(72) Inventors: Hsin-Ying HO, Kaohsiung (TW); Ying-Chung CHEN, Kaohsiung (TW); Lu-Ming LAI, Kaohsiung (TW)

(73) Assignee: Advanced Semiconductor Engineering, Inc., Kaohsiung (TW)

(21) Appl. No.: 17/187,539

(22) Filed: Feb. 26, 2021

Related U.S. Application Data
(63) Continuation of application No. 15/643,458, filed on Jul. 6, 2017.
(60) Provisional application No. 62/363,102, filed on Jul. 15, 2016.

(51) Int. Cl. H01L 25/16; F21V 8/00; G02B 6/42; H01L 31/0232; H01L 27/15; H01L 25/00; H01L 27/146; H01L 31/12; H01L 31/0203; H01L 33/48; H01S 5/02253; H01S 5/02325; H01S 5/02326

(52) U.S. Cl. CPC H01L 25/167; H01L 33/58; G02B 6/4212; G02B 6/4257; G02B 6/4206; G02B 6/002; G02B 6/0073; G02B 6/0065; G02B 6/0036; G02B 6/0045; G02B 6/0096; H01L 25/165; G02B 6/0091; G02B 6/0076; H01L 31/02327; H01L 27/15; H01L 25/50; H01L 27/14618; H01L 27/14625; H01L 31/12; H01L 31/0203; H01L 33/483; H01S 5/02253; H01S 5/02325; H01S 5/02326; G02B 6/0028; G02B 6/0025; G02B 6/0031; G02B 6/0051; G02B 6/0055; H01L 2924/12042; H01L 2933/0058; G02B 6/0018

(57) ABSTRACT

An optical module includes a carrier, a light emitter disposed on the carrier, a light detector disposed on the carrier, and a housing disposed on the carrier. The housing defines a first opening that exposes the light emitter and a second opening that exposes the light detector. The optical module further includes a first light transmission element disposed on the first opening and a second light transmission element disposed on the second opening. A first opaque layer is disposed on the first light transmission element, the first opaque layer defining a first aperture, and a second opaque layer disposed on the second light transmission element, the second opaque layer defining a second aperture.

### CROSS-REFERENCE TO RELATED APPLICATION

This application is a continuation of U.S. patent application Ser. No. 15/643,458 filed Jul. 6, 2017, which claims the benefit of and priority to U.S. Provisional Application No. 62/363,102, filed Jul. 15, 2016, the contents of which are incorporated herein by reference in their entirety.

### BACKGROUND

### 1. Technical Field

The present disclosure relates to a semiconductor package device, and to a semiconductor package device including one or more light emitting components.

### 2. Description of the Related Art

In an optical sensor module, an alignment of an aperture or a housing of a lid and a light emitter or a light detector can affect performance of the sensor module. However, offsets from a desired position may occur during manufacture of the optical sensor module. For example, an offset (e.g. shift) of a die relative to a mounting area of a carrier (an area where the die is mounted or placed) can be approximately in a range of 25 μm to 50 μm, an offset of a panel of a lid or housing relative to the carrier can be approximately 100 μm, and an offset of an aperture of the lid can be approximately 30 μm. Even if the panel of the lid is divided into individual lids, one or more shifts of approximately 50 μm may occur when assembling the die and the individual lid. It can be desirable to reduce such offsets (e.g. offsets generated during the manufacture of the optical sensor module).

In addition, a size of an opening (e.g. an opening through which light passes) of the lid or housing (defined by the lid or housing) is important for some optical positioning applications (e.g., proximity sensor) to accurately measure a distance between an object and the optical sensor module. An accuracy of the measurement result can improve as the size of the opening of the lid or housing decreases. However, a minimum size of the opening of the lid achievable for some comparative techniques is approximately 250 μm. Therefore, it can be desirable to develop an optical sensor module having a lid or housing with a small opening (e.g. an opening smaller than approximately 250 μm).

### SUMMARY

In accordance with an aspect of the present disclosure, an optical module includes a carrier, a light emitter disposed on the carrier, a light detector disposed on the carrier, and a housing disposed on the carrier. The housing defines a first opening that exposes the light emitter and a second opening that exposes the light detector. The optical module further includes a first light transmission element disposed on the first opening and a second light transmission element disposed on the second opening. A first opaque layer is disposed on the first light transmission element, the first opaque layer defining a first aperture, and a second opaque layer disposed on the second light transmission element, the second opaque layer defining a second aperture.

In accordance another aspect of the present disclosure, a method of manufacturing an optical module includes providing a carrier, placing a light emitter on the carrier, placing a light detector on the carrier, and placing a housing on the carrier, the housing defining a first opening that exposes the light emitter and a second opening that exposes the light detector. The method further includes placing a first light transmission element on the first opening, the first light transmission element including a first opaque layer that defines a first aperture, and placing a second light transmission element on the second opening, the second light transmission element including a second opaque layer that defines a second aperture.

### BRIEF DESCRIPTION OF THE DRAWINGS

FIG. 1 illustrates a cross-sectional view of some embodiments of an optical device in accordance with a first aspect of the present disclosure;

FIG. 2 illustrates a cross-sectional view of some embodiments of an optical device in accordance with the first aspect of the present disclosure;

FIG. 3A illustrates a cross-sectional view of some embodiments of a semiconductor device in accordance with a second aspect of the present disclosure;

FIG. 3B illustrates a cross-sectional view of some embodiments of a semiconductor device in accordance with the second aspect of the present disclosure; and

FIG. 4A, FIG. 4B and FIG. 4C illustrate a method for manufacturing an optical device in accordance with some embodiments of the present disclosure.

Common reference numerals are used throughout the drawings and the detailed description to indicate the same or similar components. The present disclosure can be best understood from the following detailed description taken in conjunction with the accompanying drawings.

### DETAILED DESCRIPTION

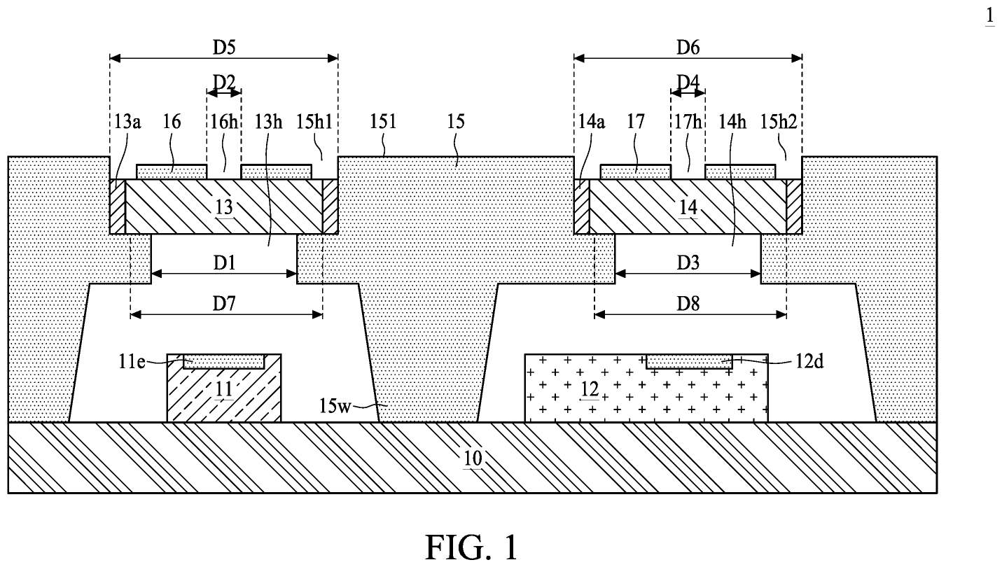

FIG. 1 illustrates a cross-sectional view of some embodiments of an optical device 1 in accordance with a first aspect of the present disclosure. The optical device 1 includes a carrier 10, a first electronic component 11, a second electronic component 12, a first light transmission element 13, a second light transmission element 14, a lid 15, a first opaque layer 16 and a second opaque layer 17.

The carrier 10 may include, for example, a printed circuit board, such as a paper-based copper foil laminate, a composite copper foil laminate, or a polymer-impregnated glass-fiber-based copper foil laminate. The carrier 10 may include an interconnection structure, such as a plurality of conductive traces or a through via. In some embodiments, the carrier 10 includes a ceramic material or a metal plate. In some embodiments, the carrier 10 may include a substrate, such as an organic substrate or a leadframe. In some embodiments, the carrier 10 may include a two-layer substrate which includes a core layer and a conductive material and/or structure disposed on an upper surface and a bottom surface of the carrier 10. The conductive material and/or structure may include a plurality of traces.

The first electronic component 11 is disposed on the carrier 10. The first electronic component 11 may include an emitting die or other optical die. For example, the first electronic component 11 may include a light-emitting diode (LED), a laser diode, or another device that may include one or more semiconductor layers. The semiconductor layers may include silicon, silicon carbide, gallium nitride, or any other semiconductor materials. The first electronic component 11 can be connected to the carrier 10 by way of flip-chip or wire-bond techniques, for example. In some embodiments, the first electronic component 11 includes an LED die bonded on the carrier 10 via a die bonding material. The LED die includes at least one wire-bonding pad. The LED die is electrically connected to the carrier 10 by a conductive wire, one end of which is bonded to the wire-bonding pad of the LED die and another end of which is bonded to a wire-bonding pad of the carrier 10. The first electronic component 11 has an active region (or light emitting area) 11e facing toward the first light transmission element 13.

The second electronic component 12 is disposed on the carrier 10 and is physically separated from the first electronic component 11. In some embodiments, the electronic component 12 may include a light detector which is, for example, a PIN diode (a diode including a p-type semiconductor region, an intrinsic semiconductor region, and an n-type semiconductor region) or a photo-diode or a photo-transistor. The electronic component 12 can be connected to the carrier, for example, by way of flip-chip or wire-bond techniques. The first electronic component 12 has an active region (or light detecting area) 12d facing toward the second light transmission element 14.

The lid (or housing) 15 is disposed on the carrier 10. The lid 15 has a wall structure 15w disposed between the electronic component 11 and the electronic component 12. The lid 15 is substantially opaque to prevent undesired light emitted by the electronic component 11 from being directly transmitted to the electronic component 12.

The lid 15 defines a first opening 13h above the first electronic component 11 and a second opening 14h above the second electronic component 12. The first opening 13h and the second opening 14h are physically separated from each other. In some embodiments, a width D1 of the first opening 13h is about equal to or greater than (e.g. is about 10% greater than, about 20% greater than, about 30% greater than, or more than about 30% greater than) an area of the light emitting area 11e of the first electronic component 11, and a width D3 of the second opening 14h is about equal to or greater than (e.g. is about 10% greater than, about 20% greater than, about 30% greater than, or more than about 30% greater than) an area of the light detecting area 12d of the second electronic component 12. For example, an area of a projection of the first opening 13h on the carrier 10 is about equal to or larger than the area of the light emitting area 11e of the first electronic component 11, and an area of a projection of the second opening 14h on the carrier 10 is about equal to or larger than the area of the light detecting area 12d of the second electronic component 12. For example, the first opening 13h is configured such that the light emitting area 11e of the first electronic component 11 is exposed (e.g., fully exposed) from the lid 15 by the first opening 13h, which can help in accurately determining a position of a center of the light emitting area 11e of the first electronic component 11 (e.g. during or after manufacture). In addition, the second opening 14h is configured such that the light detecting area 12d of the second electronic component 12 is exposed (e.g., fully exposed) from the lid 15 by the second opening 14h, which can help in accurately determining a position of a center of the light detecting area 12d of the second electronic component 12 (e.g. during or after manufacture).

The lid 15 defines a first cavity 15h1 above the first opening 13h (e.g. the first opening 13h is defined by a portion of the lid 15 that constitutes a bottom of the cavity 15h1) configured to accommodate the first light transmission element 13 and a second cavity 15h2 above the second opening 14h (e.g. the second opening 14h is defined by a portion of the lid 15 that constitutes a bottom of the cavity 15h2) configured to accommodate the second light transmission element 14. In some embodiments, a width D5 of the first cavity 15h1 is greater than (e.g. is about 10% greater than, about 20% greater than, about 30% greater than, or more than about 30% greater than) the width D1 of the first opening 13h, and a width D6 of the second cavity 15h2 is greater than (e.g. is about 10% greater than, about 20% greater than, about 30% greater than, or more than about 30% greater than) the width D3 of the second opening 14h. The first cavity 15h1 and the second cavity 15h2 are physically separated from each other.

The first light transmission element 13 is disposed within the first cavity 15h1 and on the first opening 13h. The first light transmission element 13 is configured to allow transmission of light emitted from the first electronic component 11. In some embodiments, the first light transmission element 13 is a lens. In some embodiments a width D7 of the first light transmission element 13 is greater than the width D1 of the first opening 13h and less than or about equal to the width D5 of the first cavity 15h1. In some embodiments, an adhesive layer 13a is disposed between the first light transmission element 13 and a sidewall of the first cavity 15h1 (e.g. in some embodiments in which the width D7 of the first light transmission element 13 is less than the width D5 of the first cavity 15h1). In some embodiments, the adhesive layer 13a includes thermal cured materials or optical cured materials.

The second light transmission element 14 is disposed within the second cavity 15h2 and on the second opening 14h. The second light transmission element 14 is physically separated from the first light transmission element 13. The second light transmission element 14 is configured to allow the transmission of the light received by the second electronic component 12. In some embodiments, the second light transmission element 14 is a lens. In some embodiments a width D8 of the second light transmission element 14 is greater than the width D3 of the first opening 14h and less than or about equal to the width D6 of the second cavity 15h2. In some embodiments, an adhesive layer 14a is disposed between the second light transmission element 13 and a sidewall of the second cavity 15h2 (e.g. in some embodiments in which the width D8 of the first light transmission element 14 is less than the width D6 of the second cavity 15h2).

The first opaque layer 16 is disposed on the first light transmission element 13. In some embodiments, the first opaque layer 16 may include a light absorbing layer, ink, photoresist or a metal layer. In some embodiments, the first opaque layer 16 is recessed from a top surface 151 of the lid 15. The first opaque layer 16 defines a first aperture 16h. The light emitted by the first electronic component 11 selectively passes through the first aperture 16h, and other light emitted by the first electronic component 11 is substantially blocked or absorbed by the first opaque layer 16. A center of the first aperture 16h is substantially aligned with the center of the light emitting area 11e of the first electronic component 11. A width D2 of the first aperture 16h is less than the width D1 of the first opening 13h. In some embodiments, the width of the first aperture 16h is less than about 250 μm.

The second opaque layer 17 is disposed on the second light transmission element 14. The second opaque layer 17 is physically separated from the first opaque layer 16. In some embodiments, the second opaque layer 17 may include a light absorbing layer, ink, photoresist or a metal layer. In some embodiments, the second opaque layer 17 is recessed from the top surface 151 of the lid 15. The second opaque layer 17 defines a second aperture 17h. The light emitted toward the second electronic component 12 selectively passes through the second aperture 17h, and other light emitted toward the second electronic component 12 is substantially blocked or absorbed by the second opaque layer 17. A center of the second aperture 17h is substantially aligned with the center of the light detecting area 12d of the second electronic component 12. A width D4 of the second aperture 17h is less than the width D3 of the second opening 14h. In some embodiments, the width of the second aperture 17h is less than about 250 μm.

In a comparative optical module, an aperture is directly formed in a lid by a machine; however, due to constraints of some such processes, the size of the aperture of the lid is not less than about 250 μm. In accordance with some embodiments shown in FIG. 1, the first and second opaque layers 16, 17 are respectively formed by printing or coating ink on the first and second light transmission elements 13, 14. The first aperture 16h and the second aperture 17h are formed by lithographic technique, and thus the size of the apertures can be readily scaled down (e.g., to less than about 250 μm). By miniaturizing such apertures, undesired light (e.g., light from an external environment) which may be inadvertently detected by the light detector can be reduced, which can help to reduce a deviation between a measured or detected position and a real position of an object detected by the optical module, thus increasing the accuracy of the optical module.

In some embodiments, a panel including a light transmission element and an opaque layer may be placed on the lid to cover both of the light emitter and the light detector. However, since the relative locations of the apertures of the opaque layer may be fixed, it can be difficult to simultaneously control the alignment of the aperture of the opaque layer with the light emitter or the light detector. For example, one aperture of the opaque layer may be aligned with the light emitter, but another aperture may be misaligned with the light detector. In accordance with the embodiments shown in FIG. 1, the light transmission elements 13, 14 and the opaque layers 16, 17 are individually disposed over the first electronic component 11 (e.g. the light emitter) and over the second electronic component 12 (e.g. the light detector). The respective centers of the apertures 16h, 17h and the centers of the light emitting area 11e of the light emitter 11 and the light detecting area 12d of the light detector 12 can be individually detected and aligned, which can help to reduce an offset of alignment and to increase the accuracy of the optical device 1.

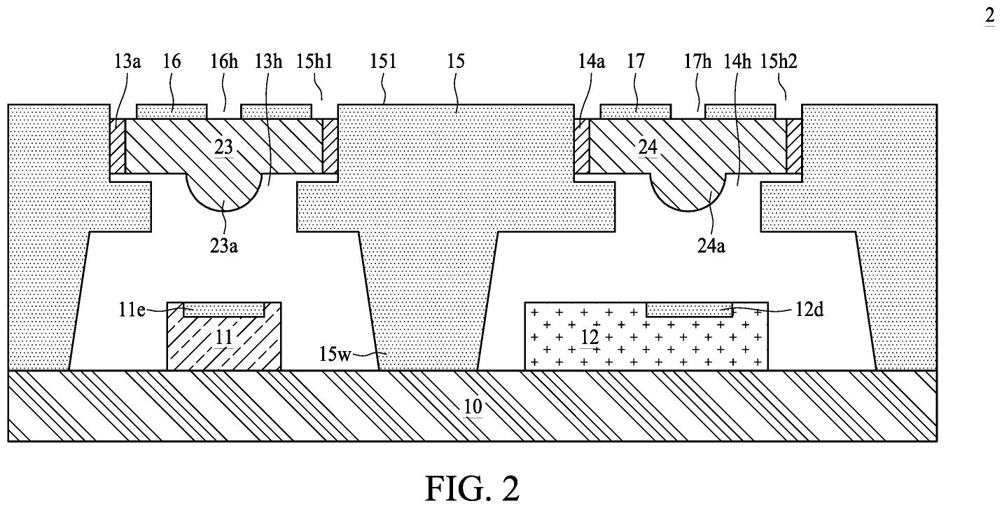

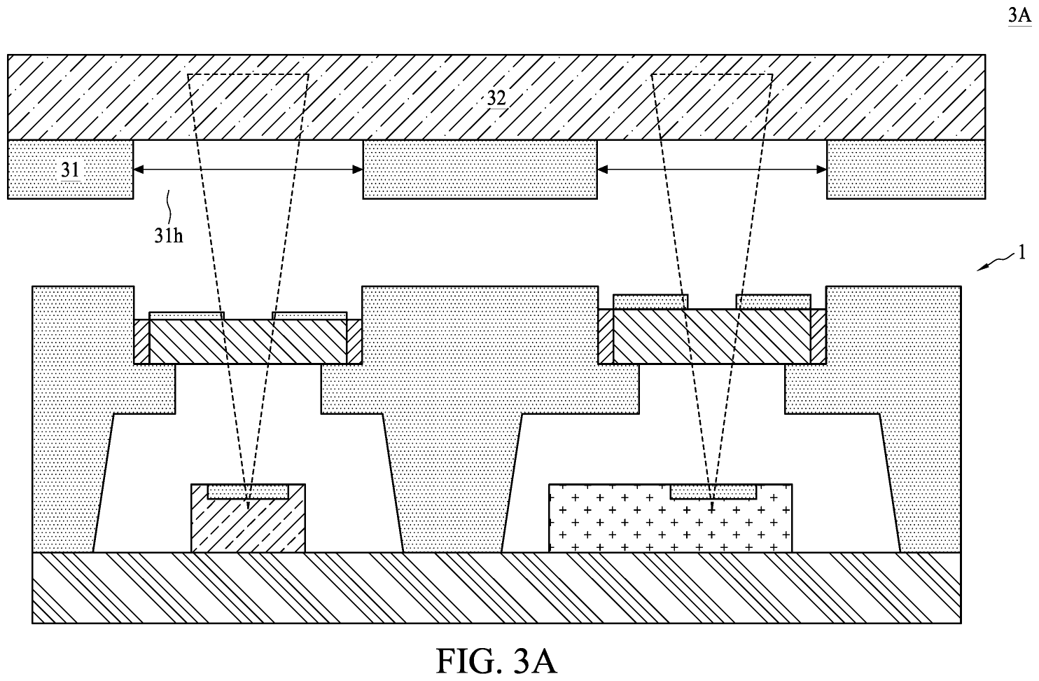

FIG. 2 illustrates a cross-sectional view of some embodiments of an optical device 2 in accordance with the first aspect of the present disclosure. The optical device 2 is similar to the optical device 1 shown in FIG. 1 except that first and second light transmission elements 23, 24 of the optical device 2 are plano-convex lenses. As shown in FIG. 2, a convex surface 23a of the first light transmission element 23 faces toward a first electronic component 11, and a convex surface 24a of the second light transmission element 24 faces a second electronic component 12. The convex surface 23a may protrude into an aperture 13h defined by the lid 15. The convex surface 24a may protrude into an aperture 14h defined by the lid 15. The plano-convex lenses may increase the density of the light that reaches the electronic components, which can help to improve the performance of the optical device 2.

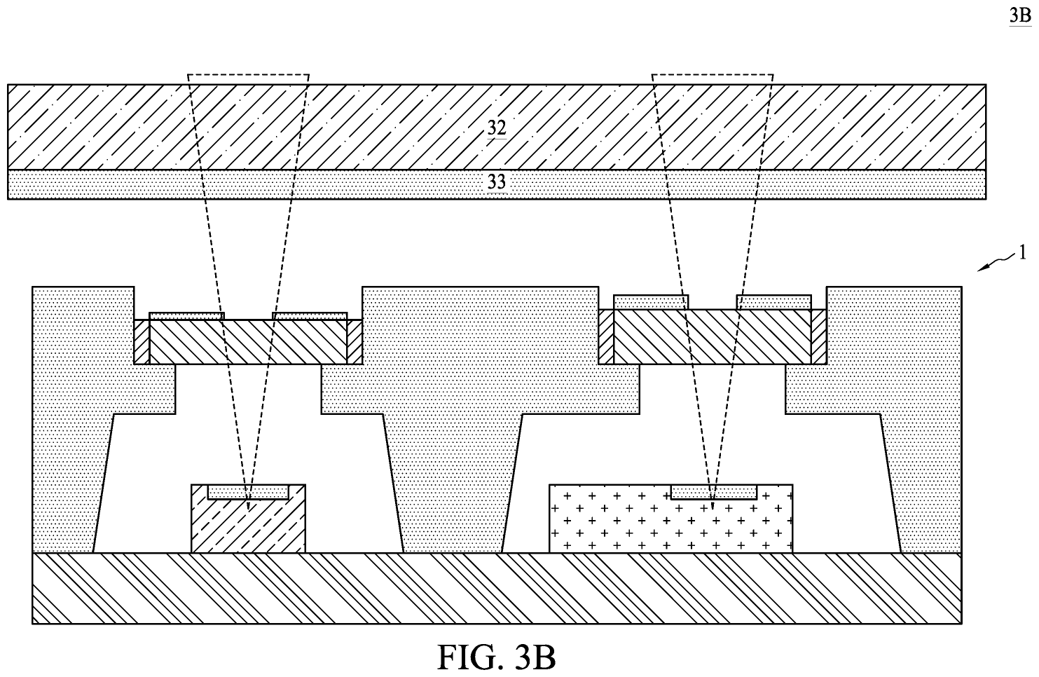

FIG. 3A illustrates a cross-sectional view of some embodiments of a semiconductor device 3A in accordance with a second aspect of the present disclosure. The semiconductor device 3A includes the optical device 1 as shown in FIG. 1, a third opaque layer 31 and a lens 32. Light cones, depicted by dashed lines, show some possible paths of light that can be transmitted to or from electronic components of the optical device 1. In some embodiments, the semiconductor device 3A can be implemented with the optical device 2 shown in FIG. 2 in place of, or in addition to, the optical device 1.

The third opaque layer 31 is disposed on the optical device 1. The third opaque layer 31 defines an opening 31h that allows light to pass through. The lens 32 is disposed on the third opaque layer 31. In some embodiments, the lens 32 may include or may be a glass portion (e.g. a glass panel) of a cell phone, a tablet, a notebook, a camera or other electronic devices equipped with a proximity sensor.

FIG. 3B illustrates a cross-sectional view of some embodiments of a semiconductor device 3B in accordance with the second aspect of the present disclosure. The semiconductor device 3B is similar to the semiconductor device 3A shown in FIG. 3A except that the second opaque layer 31 is replaced by a light filter layer 33. Light cones, depicted by dashed lines, show some possible paths of light that can be transmitted to or from electronic components of the optical device 1. The light filter layer 33 does not define an opening (e.g. is devoid of an opening over the apertures of the optical device 1). The light filter layer 33 is configured to allow light with predetermined wavelengths to pass through. In some embodiments, the light filter layer 33 is implemented in conjunction with the third opaque layer 31.

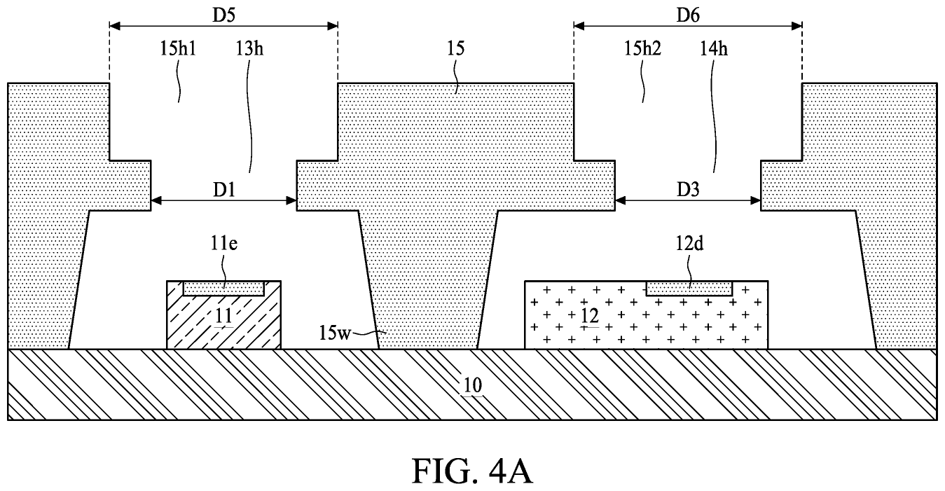

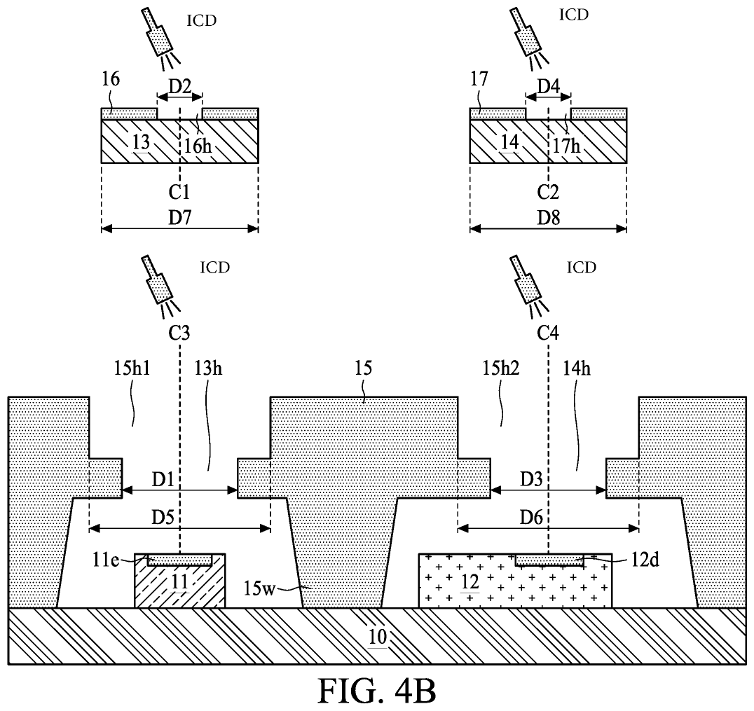

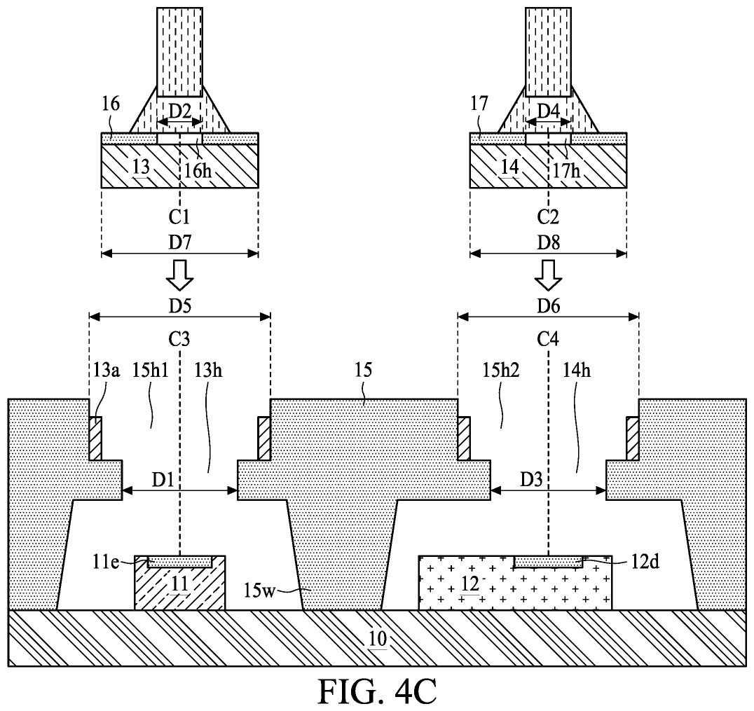

FIG. 4A, FIG. 4B and FIG. 4C illustrate a method for manufacturing an optical device 1 as shown in FIG. 1 in accordance with some embodiments of the present disclosure. Although some processes, operations or steps are described in the following with respect to each of a plurality of components, any of those processes, operations or steps may be selectively performed with respect to one of the plurality of components, or with respect to some number in between one and the full plurality of components.

Referring to FIG. 4A, the carrier 10 is provided. The first electronic component 11 (e.g., a light emitter) and the second electronic component 12 (e.g., a light detector) are placed on the carrier 10. The first electronic component 11 and the second electronic component 12 are physically separated from each other.

The lid (or housing) 15 is placed on the carrier 10. The lid 15 is arranged so that the wall structure 15w of the lid 15 is disposed between the electronic component 11 and the electronic component 12, the first opening 13h of the lid 15 is disposed above the first electronic component 11 and the second opening 14h of the lid 15 is disposed above the second electronic component 12. In some embodiments, the width D1 of the first opening 13h is about equal to or greater than (e.g. is about 10% greater than, about 20% greater than, about 30% greater than, or greater than about 30% greater than) an area of the light emitting area 11e of the first electronic component 11, and the width D3 of the second opening 14h is about equal to or greater than (e.g. is about 10% greater than, about 20% greater than, about 30% greater than, or greater than about 30% greater than) an area of the light detecting area 12d of the second electronic component 12. For example, the first opening 13h is configured such that the light emitting area 11e of the first electronic component 11 is exposed from the lid 15 by the first opening 13h, which can help in accurately determining a location of a center of the light emitting area 11e of the first electronic component 11 in subsequent operations. In addition, the second opening 14h is configured such that the light detecting area 12d of the second electronic component 12 is exposed from the lid 15 by the second opening 13h, which can help in accurately determining a location of a center of the light detecting area 12d of the second electronic component 12 in subsequent operations. The first opening 13h and the second opening 14h are physically separated from each other.

The lid 15 has a first cavity 15h1 above the first opening 13h and a second cavity 15h2 above the second opening 14h. In some embodiments, a width D5 of the first cavity 15h1 is greater than a width D1 of the first opening 13h, and a width D6 of the second cavity 15h2 is greater than a width D3 of the second opening 14h. The first cavity 15h1 and the second cavity 15h2 are physically separated from each other.

In some manufacturing process embodiments, there is a first offset tolerance for placing the lid 15 (e.g. on the carrier 10) and there is a second offset tolerance for placing the first or second electronic components 11, 12 (e.g. on the carrier 10). At least one of the widths D1, D3 of the first opening 13h and the second opening 14h is larger than or about equal to a sum of the first offset tolerance, the second offset tolerance and (i) a width of the area of the light emitting area 11e of the first electronic component 11 or (ii) a width of the area of the light detecting area 12d of the second electronic component 12.

Referring to FIG. 4B, the first light transmission element 13 and the second light transmission element 14 are provided. In some embodiments, the first and second light transmission elements 13, 14 are provided by dividing a panel of a transmission element into multiple individual light transmission elements. In some embodiments the width D7 of the first light transmission element 13 is greater than the width D1 of the first opening 13h and less than or about equal to the width D5 of the first cavity 15h1 (e.g. is about 10% less than, about 20% less than, about 30% less than, or less than about 30% less than). The width D8 of the second light transmission element 14 is greater than the width D3 of the first opening 14h and less than or about equal to the width D6 of the second cavity 15h2 (e.g. is about 10% less than, about 20% less than, about 30% less than, or less than about 30% less than).

The first and second opaque layers 16, 17 are respectively formed on the first and second light transmission elements 13, 14. In some embodiments, the first and second opaque layers 16, 17 can be formed by plating or coating ink on the first and second light transmission elements 13, 14. The first and second apertures 16h, 17h are then formed to penetrate the first and second opaque layers 16, 17 and to expose a portion of the first and second light transmission elements 13, 14. In some embodiments, the first and second apertures 16h, 17h can be formed by photolithography, chemical etching, laser drilling, or other suitable processes. In some embodiments, the width D2 of the first aperture 16h is less than the width D1 of the first opening 13h, and the width D4 of the second aperture 17h is less than the width D3 of the second opening 14h. In some embodiments, the width of each of the first and second apertures 16h, 17h is less than about 250 μm.

A center C1 of the first aperture 16h and a center C2 of the second aperture 17h can be detected or calculated. The center C1 or C2 of the first aperture 16h or the second aperture 17h is determined by an image capturing device ICD and a processor. Detecting or calculating a center C3 of the light emitting area 11e of the first electronic component 11 and a center C4 of the light detecting area 12d of the second electronic component 12 can be performed in a similar manner. For example, the center C3 or C4 of the light emitting area 11e of the first electronic component 11 or the light detecting area 12d of the second electronic component 12 is determined by an image capturing device ICD and a processor.

Referring to FIG. 4C, the center C1 of the first aperture 16h is aligned with the center C3 of the light emitting area 11e of the first electronic component 11, and the first light transmission element 13 together with the first opaque layer 16 are disposed within the first cavity 15h1 by, for example, a pick and place operation. The center C2 of the second aperture 17h is aligned with the center C4 of the light detecting area 12d of the second electronic component 12, and the second light transmission element 14 together with the second opaque layer 17 are disposed within the second cavity 15h2 by, for example, a pick and place operation. In some embodiments, the first opaque layer 16 and the second opaque layer 17 are recessed from a top surface 151 of the lid 15.

In some embodiments, before the placement of the first and second light transmission elements 13, 14, the adhesive layer 13a can be placed adjacent to sidewalls of the first and second cavities 15h1, 15h2, which can help to secure the first and second light transmission elements 13, 14 (e.g. in implementations in which the widths D7, D8 of the first and second light transmission elements 13, 14 are less than the widths D5, D6 of the first and second cavities 15h1, 15h2). In some embodiments, the adhesive layer 13a includes thermal cured materials or optical cured materials.

As used herein, the terms “substantially,” “substantial,” “approximately,” and “about” are used to denote and account for small variations. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. As another example, a thickness of a film or a layer being “substantially uniform” can refer to a standard deviation of less than or equal to ±10% of an average thickness of the film or the layer, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within 50 μm of lying along a same plane, such as within 40 within 30 within 20 within 10 or within 1 μm of lying along the same plane. Two components can be deemed to be “substantially aligned” if, for example, the two components overlap or are within 200 within 150 within 100 within 50 within 40 within 30 within 20 within 10 or within 1 μm of overlapping. Two surfaces or components can be deemed to be “substantially perpendicular” if an angle therebetween is, for example, 90°±10°, such as ±5°, ±4°, ±3°, ±2°, ±1°, ±0.5°, ±0.1°, or ±0.05°. When used in conjunction with an event or circumstance, the terms “substantially,” “substantial,” “approximately,” and “about” can refer to instances in which the event or circumstance occurs precisely, as well as instances in which the event or circumstance occurs to a close approximation.

In the description of some embodiments, a component provided “on” another component can encompass cases where the former component is directly on (e.g., in physical contact with) the latter component, as well as cases where one or more intervening components are located between the former component and the latter component.

Additionally, amounts, ratios, and other numerical values are sometimes presented herein in a range format. It can be understood that such range formats are used for convenience and brevity, and should be understood flexibly to include not only numerical values explicitly specified as limits of a range, but also all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It can be clearly understood by those skilled in the art that various changes may be made, and equivalent elements may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and such. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. A method of manufacturing an optical module, comprising:
providing a carrier having a first electronic component disposed thereon;
placing a lid on the carrier, the lid defining a first opening; and
aligning an active region of the first electronic component to a first aperture of a first opaque layer on a first light transmission element.

2. The method of claim 1, further comprising printing or coating the first opaque layer on the first light transmission element to define the first aperture.

3. The method of claim 1, wherein the aligning operation is conducted by an image capturing device.

4. The method of claim 3, further comprising capturing an image of the active region of the first electronic component that exposed from the first opening.

5. The method of claim 3, further comprising capturing an image of the first aperture of the first light transmission element.

6. The method of claim 1, further comprising:
placing the first light transmission element within the first opening by a first pick and place operation.

7. The method of claim 6, wherein the first light transmission element is accommodated in a first cavity of the first opening.

8. The method of claim 7, further comprising:
forming a first adhesive layer on a sidewall of the first cavity.

9. The method of claim 8, wherein the first adhesive layer is formed before placing the first light transmission element in the first cavity.

10. The method of claim 1, wherein placing the lid on the carrier has a first offset tolerance and placing the first electronic component on the carrier has a second offset tolerance, and a width of the first opening is larger than or equal to a sum of the first offset tolerance, the second offset tolerance and a width of the active region of the first electronic component.

11. The method of claim 1, wherein the aligning operation further comprises aligning a center of the active region to a center of the first aperture.

12. The method of claim 6, further comprising:
aligning an active region of a second electronic component disposed on the carrier to a second aperture of a second opaque layer on a second light transmission element; and
placing the second light transmission element within a second opening of the lid by a second pick and place operation, wherein the first pick and place operation and the second pick and place operation are performed separately.

13. The method of claim 10, further comprising:
placing a second light transmission element within a second opening of the lid, wherein placing the second electronic component has a third offset tolerance different from the second offset tolerance.

14. The method of claim 12, wherein the second light transmission element is accommodated in a second cavity of the second opening, and the method further comprises:
before placing the second light transmission element in the second cavity, forming a second adhesive layer on a sidewall of the second cavity.

15. The method of claim 12, further comprising:
dividing a panel of a light transmission element to form the first light transmission element and the second light transmission element.

16. An optical module, comprising:
a carrier;
an electronic component on the carrier;
a lid on the carrier, the lid defining an opening that exposes an active area of the electronic component;
a light transmission element within the opening; and
an adhesive layer between the light transmission element and a sidewall of the lid defining the opening, wherein the light transmission element is secured by the adhesive layer.

17. The optical module of claim 16, wherein the opening is wider at a side proximal to the light transmission element and narrower at a side proximal to the electronic component.

18. The optical module of claim 16, wherein the adhesive layer comprises a thermal cured material or an optical cured material.

19. The optical module of claim 18, wherein a part of the adhesive layer is between the electronic component and the light transmission element.

20. The optical module of claim 18, wherein the electronic component has a surface facing the light transmission element, and the surface has a first portion overlapped with the lid and a second portion exposed from the lid.
